(19) United States
(12) Patent Application Publication
(10) Pub. No.: US 2025/0364494 A1
(43) Pub. Date: Nov. 27, 2025

(54) 3DIC Interconnect Apparatus and Method

(71) Applicant: Taiwan Semiconductor Manufacturing Co., Ltd., Hsinchu (TW)

(72) Inventors: Shu-Ting Tsai, Kaohsiung City (TW); Dun-Nian Yaung, Taipei City (TW); Jen-Cheng Liu, Hsinchu (TW); Chun-Chieh Chuang, Tainan City (TW); Chia-Chieh Lin, Kaohsiung City (TW); U-Ting Chen, Wanluan Township (TW)

(21) Appl. No.: 19/292,277

(22) Filed: Aug. 6, 2025

Related U.S. Application Data
(63) Continuation of application No. 18/359,311, filed on Jul. 26, 2023.
Application No. 18/359,311 is a continuation of application No. 16/048,777, filed on Jul. 30, 2018, now Pat. No. 11,798,916.
Application No. 16/048,777 is a division of application No. 14/135,153, filed on Dec. 19, 2013, now Pat. No. 10,056,353.

(51) Int. Cl. H01L 25/065; H01L 21/768; H01L 23/00; H01L 23/48; H01L 23/532; H01L 25/00

(52) U.S. Cl. CPC H01L 25/0657; H01L 21/76898; H01L 23/481; H01L 24/92; H01L 25/50; H01L 21/76805; H01L 21/76831; H01L 23/53223; H01L 23/53238; H01L 23/53266; H01L 24/80; H01L 24/82; H01L 2224/24145; H01L 2224/80896; H01L 2224/8203; H01L 2224/821; H01L 2224/82106; H01L 2224/9202; H01L 2224/9212; H01L 2225/06541; H01L 2924/0002

(57) ABSTRACT

An interconnect apparatus and a method of forming the interconnect apparatus is provided. Two integrated circuits are bonded together. A first opening is formed through one of the substrates. A multi-layer dielectric film is formed along sidewalls and a bottom of the first opening. A second opening is formed extending from the first opening to pads in the integrated circuits. A dielectric liner is formed, and the opening is filled with a conductive material to form a conductive plug.

### PRIORITY CLAIM AND CROSS-REFERENCE

This application is a continuation of U.S. application Ser. No. 18/359,311, filed on Jul. 26, 2023, which is a continuation U.S. application Ser. No. 16/048,777, filed on Jul. 30, 2018, now U.S. Pat. No. 11,798,916 issued Oct. 24, 2023, which is a divisional U.S. application Ser. No. 14/135,153, filed on Dec. 19, 2013, now U.S. Pat. No. 10,056,353 issued Aug. 21, 2018, each application is hereby incorporated herein by reference.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size (e.g., shrinking the semiconductor process node towards the sub-20 nm node), which allows more components to be integrated into a given area. As the demand for miniaturization, higher speed and greater bandwidth, as well as lower power consumption and latency has grown recently, there has grown a need for smaller and more creative packaging techniques of semiconductor dies.

As semiconductor technologies further advance, stacked semiconductor devices, e.g., 3D integrated circuits (3DIC), have emerged as an effective alternative to further reduce the physical size of a semiconductor device. In a stacked semiconductor device, active circuits such as logic, memory, processor circuits and the like are fabricated on different semiconductor wafers. Two or more semiconductor wafers may be installed on top of one another to further reduce the form factor of the semiconductor device.

Two semiconductor wafers may be bonded together through suitable bonding techniques. The commonly used bonding techniques include direct bonding, chemically activated bonding, plasma activated bonding, anodic bonding, eutectic bonding, glass frit bonding, adhesive bonding, thermo-compressive bonding, reactive bonding and/or the like. An electrical connection may be provided between the stacked semiconductor wafers. The stacked semiconductor devices may provide a higher density with smaller form factors and allow for increased performance and lower power consumption.

### BRIEF DESCRIPTION OF THE DRAWINGS

For a more complete understanding of the present disclosure, and the advantages thereof, reference is now made to the following descriptions taken in conjunction with the accompanying drawings, in which:

FIGS. 1-6 are cross-sectional views of various processing steps during fabrication of an interconnect in accordance with an embodiment;

FIG. 7 is a cross-sectional view of an intermediate processing step during fabrication of an interconnect in accordance with another embodiment; and

FIG. 8 is a flow diagram illustrating a method of forming an interconnect in accordance with an embodiment.

Corresponding numerals and symbols in the different figures generally refer to corresponding parts unless otherwise indicated. The figures are drawn to clearly illustrate the relevant aspects of the various embodiments and are not necessarily drawn to scale.

### DETAILED DESCRIPTION

The making and using of embodiments of the present disclosure are discussed in detail below. It should be appreciated, however, that the present disclosure provides many applicable inventive concepts that can be embodied in a wide variety of specific contexts. The specific embodiments discussed are merely illustrative of specific ways to make and use the invention, and do not limit the scope of the invention.

The present disclosure will be described with respect to embodiments in a specific context, namely, a method for forming interconnect structures for a stacked semiconductor device. Other embodiments, however, may be applied to a variety of semiconductor devices. Hereinafter, various embodiments will be explained in detail with reference to the accompanying drawings.

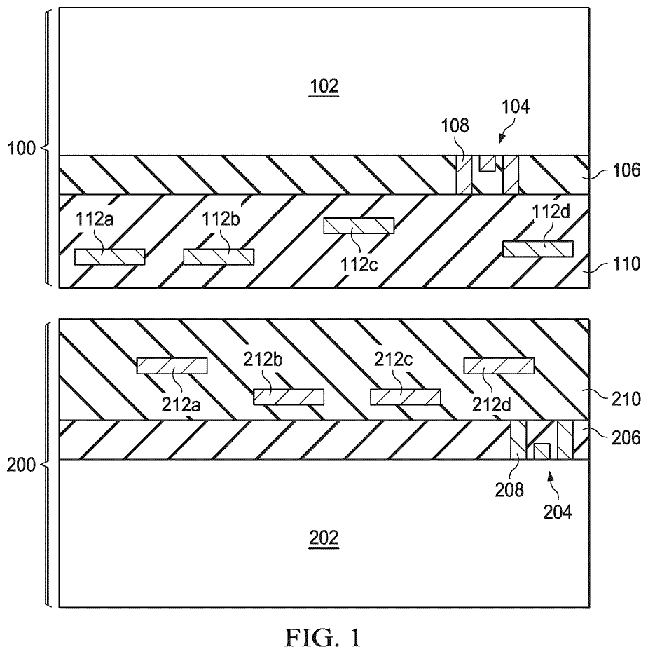

FIGS. 1-6 illustrate various intermediate steps of forming an interconnect structure between two bonded wafers or dies in accordance with an embodiment. Referring first to FIG. 1, a first wafer 100 and a second wafer 200 is shown prior to a bonding process in accordance with various embodiments. In an embodiment, the second wafer 200 has similar features as the first wafer 100, and for the purpose of the following discussion, the features of the second wafer 200 having reference numerals of the form “2xx” are similar to features of the first wafer 100 having reference numerals of the form “1xx,” the “xx” being the same numerals for the first wafer 100 and the second wafer 200. The various elements of the first wafer 100 and the second wafer 200 will be referred to as the “first <element>1xx” and the “second <element>2xx,” respectively.

In an embodiment, the first wafer 100 comprises a first substrate 102 having a first electrical circuit (illustrated collectively by first electrical circuitry 104) formed thereon. The first substrate 102 may comprise, for example, bulk silicon, doped or undoped, or an active layer of a semiconductor-on-insulator (SOI) substrate. Generally, an SOI substrate comprises a layer of a semiconductor material, such as silicon, formed on an insulator layer. The insulator layer may be, for example, a buried oxide (BOX) layer or a silicon oxide layer. The insulator layer is provided on a substrate, typically a silicon or glass substrate. Other substrates, such as a multi-layered or gradient substrate may also be used.

The first electrical circuitry 104 formed on the first substrate 102 may be any type of circuitry suitable for a particular application. In an embodiment, the circuitry includes electrical devices formed on the substrate with one or more dielectric layers overlying the electrical devices. Metal layers may be formed between dielectric layers to route electrical signals between the electrical devices. Electrical devices may also be formed in one or more dielectric layers.

For example, the first electrical circuitry 104 may include various N-type metal-oxide semiconductor (NMOS) and/or P-type metal-oxide semiconductor (PMOS) devices, such as transistors, capacitors, resistors, diodes, photo-diodes, fuses, and the like, interconnected to perform one or more functions. The functions may include memory structures, processing structures, sensors, amplifiers, power distribution, input/output circuitry, or the like. One of ordinary skill in the art will appreciate that the above examples are provided for illustrative purposes only to further explain applications of the present invention and are not meant to limit the present invention in any manner. Other circuitry may be used as appropriate for a given application.

Also shown in FIG. 1 is a first inter-layer dielectric (ILD)/inter-metallization dielectric (IMD) layer 106. The first ILD layer 106 may be formed, for example, of a low-K dielectric material, such as phosphosilicate glass (PSG), borophosphosilicate glass (BPSG), FSG, SiOₓC_{y}, Spin-On-Glass, Spin-On-Polymers, silicon carbon material, compounds thereof, composites thereof, combinations thereof, or the like, by any suitable method known in the art, such as spinning, chemical vapor deposition (CVD), and plasma-enhanced CVD (PECVD). It should also be noted that the first ILD layer 106 may comprise a plurality of dielectric layers.

First contacts 108 are formed through the first ILD layer 106 to provide an electrical contact to the first electrical circuitry 104. The first contacts 108 may be formed, for example, by using photolithography techniques to deposit and pattern a photoresist material on the first ILD layer 106 to expose portions of the first ILD layer 106 that are to become the first contacts 108. An etch process, such as an anisotropic dry etch process, may be used to create openings in the first ILD layer 106. The openings may be lined with a diffusion barrier layer and/or an adhesion layer (not shown), and filled with a conductive material. The diffusion barrier layer comprises one or more layers of TaN, Ta, TiN, Ti, CoW, or the like, and the conductive material comprises copper, tungsten, aluminum, silver, and combinations thereof, or the like, thereby forming the first contacts 108 as illustrated in FIG. 1.

One or more additional ILD layers 110 and the first interconnect lines 112a-112d (collectively referred to as first interconnect lines 112) form metallization layers over the first ILD layer 106. Generally, the one or more additional ILD layers 110 and the associated metallization layers are used to interconnect the electrical circuitry to each other and to provide an external electrical connection. The additional ILD layers 110 may be formed of a low-K dielectric material, such as fluorosilicate glass (FSG) formed by PECVD techniques or high-density plasma chemical vapor deposition (HDPCVD) or the like, and may include intermediate etch stop layers. External contacts (not shown) may be formed in an uppermost layer.

It should also be noted that one or more etch stop layers (not shown) may be positioned between adjacent ones of the ILD layers, e.g., the first ILD layer 106 and the additional ILD layers 110. Generally, the etch stop layers provide a mechanism to stop an etching process when forming vias and/or contacts. The etch stop layers are formed of a dielectric material having a different etch selectivity from adjacent layers, e.g., the underlying first substrate 102 and the overlying ILD layers 106/110. In an embodiment, etch stop layers may be formed of SiN, SiCN, SiCO, CN, combinations thereof, or the like, deposited by CVD or PECVD techniques.

In an embodiment, the first wafer 100 is a backside illumination sensor (BIS) and the second wafer 200 is a logic circuit, such as an ASIC device. In this embodiment, the first electrical circuitry 104 includes photo active regions, such as photo-diodes formed by implanting impurity ions into the epitaxial layer. Furthermore, the photo active regions may be a PN junction photo-diode, a PNP photo-transistor, an NPN photo-transistor or the like. The BIS sensor may be formed in an epitaxial layer over a silicon substrate.

The second wafer 200 may comprise a logic circuit, an analog-to-digital converter, a data processing circuit, a memory circuit, a bias circuit, a reference circuit, and the like. In an embodiment, the second wafer 200 has similar features as the first wafer 100. For example, the second wafer 200 includes a second substrate 202, second electrical circuitry 204, a second ILD layer 206, second contacts 208, second ILD layers 210, and second interconnect lines 212 (labeled 212a, 212b, 212c, and 212d).

In an embodiment, the first wafer 100 and the second wafer 200 are arranged with the device sides of the first substrate 102 and the second substrate 202 facing each other as illustrated in FIG. 1. As discussed in greater detail below, an opening will be formed extending from a backside (opposite the device side) of the first wafer 100 to the selected portions of the second interconnect lines 212 of the second wafer 200, such that portions of selected first interconnect lines 112 of the first wafer 100 will also be exposed. The opening will be subsequently filled with a conductive material, thereby forming an electrical contact on the backside of the first wafer to the interconnect lines of the first wafer 100 and the second wafer 200.

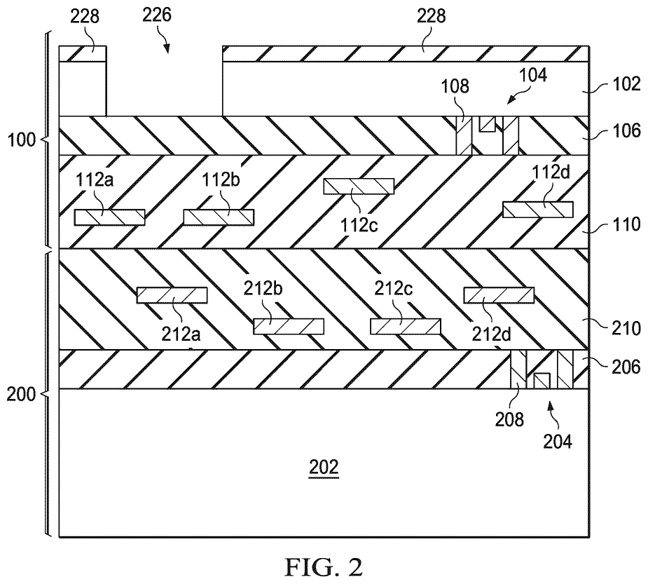

FIG. 2 illustrates the first wafer 100 and the second wafer 200 after bonding in accordance with an embodiment. As shown in FIG. 1, the first wafer 100 will be stacked and bonded on top of the second wafer 200. The first wafer 100 and the second wafer 200 may be bonded using, for example, a direct bonding process such as metal-to-metal bonding (e.g., copper-to-copper bonding), dielectric-to-dielectric bonding (e.g., oxide-to-oxide bonding), metal-to-dielectric bonding (e.g., oxide-to-copper bonding), any combinations thereof and/or the like.

It should be noted that the bonding may be at wafer level, wherein the first wafer 100 and the second wafer 200 are bonded together, and are then singulated into separated dies. Alternatively, the bonding may be performed at the die-to-die level, or the die-to-wafer level.

After the first wafer 100 and the second wafer 200 are bonded, a thinning process may be applied to the backside of the first wafer 100. In an embodiment in which the first substrate 102 is a BIS sensor, the thinning process serves to allow more light to pass through from the backside of the first substrate to the photo-active regions without being absorbed by the substrate. In an embodiment in which the BIS sensor is fabricated in an epitaxial layer, the backside of the first wafer 100 may be thinned until the epitaxial layer is exposed. The thinning process may be implemented by using suitable techniques such as grinding, polishing, a SMARTCUT® procedure, an ELTRAN® procedure, and/or chemical etching.

Also shown in FIG. 2 is a first opening 226. As discussed in greater detail below, an electrical connection will be formed extending from a backside of the first wafer 100 to select ones of the second interconnect lines 212 of the second wafer 200. The first opening 226 represents the opening in which the backside contact will be formed. The first opening 226 may be formed using photolithography techniques. Generally, photolithography techniques involve depositing a photoresist material, which is subsequently irradiated (exposed) and developed to remove a portion of the photoresist material. The remaining photoresist material protects the underlying material from subsequent processing steps, such as etching.

Also shown in FIG. 2 is an optional anti-reflection coating (ARC) layer 228. The ARC layer 228 reduces the reflection of the exposure light used during the photolithography process to pattern a patterned mask (not shown), which reflection may cause inaccuracies in the patterning. The ARC layer 228 may be formed of a nitride material (e.g., silicon nitride), an organic material (e.g., silicon carbide), an oxide material, high-k dielectric, and the like. The ARC layer 228 may be formed using suitable techniques such as CVD and/or the like.

Other layers may be used in the patterning process. For example, one or more optional hard mask layers may be used to pattern the first substrate 102. Generally, one or more hard mask layers may be useful in embodiments in which the etching process requires masking in addition to the masking provided by the photoresist material. During the subsequent etching process to pattern the first substrate 102, the patterned photoresist mask will also be etched, although the etch rate of the photoresist material may not be as high as the etch rate of the first substrate 102. If the etch process is such that the patterned photoresist mask would be consumed before the etching process is completed, then an additional hard mask may be utilized. The material of the hard mask layer or layers is selected such that the hard mask layer(s) exhibit a lower etch rate than the underlying materials, such as the materials of the first substrate 102.

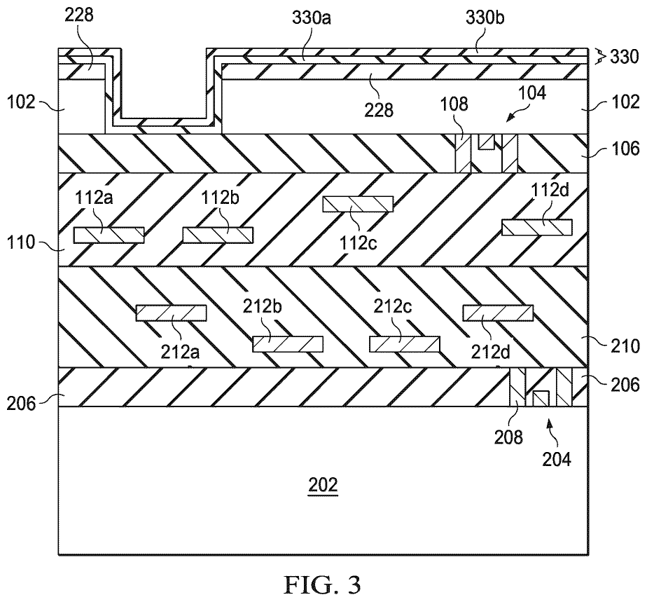

Referring now to FIG. 3, a multi-layered dielectric film 330 is formed over the backside of the first substrate 102 and along sidewalls of the first opening 226 in accordance with an embodiment. As will be discussed in greater detail below, the multi-layered dielectric film 330 provides greater passivation and isolation between through via structures and device circuits/pixel arrays. The multi-layered dielectric film 330 provides greater protection than a single film during, for example, a subsequent etch process to form electrical contacts to selected ones of the first interconnect structures 112 and the second interconnect structures 212. For example, an etch process such as a plasma etch may result in damage to the first substrate 102 as well as the dielectric layers (e.g., the ILD layers 106, 110, and 210). Additionally, the multi-layered dielectric film 330 may provide greater protection against metal ions diffusing into the first substrate 102 and the dielectric layers.

FIG. 3 illustrates an embodiment in which the multi-layered dielectric film 330 comprises a first dielectric film 330a and a second dielectric film 330b. An example of dielectric materials that may be used is a nitride material for the first dielectric film 330a and an oxide for the second dielectric film 330b. The nitride layer, such as a silicon nitride (Si₃N₄) layer, may be formed using CVD techniques using silane and ammonia as precursor gases, and deposition temperatures ranging from 550° to 900° Celsius (C). The oxide layer, such as a silicon dioxide layer, may be formed by thermal oxidation or by CVD techniques using tetra-ethyl-ortho-silicate (TEOS) and oxygen as precursor. In an embodiment, the first dielectric film 330a has a thickness from about 200 Å to about 8,000 Å, and the second dielectric film 330b has a thickness from about 200 Å to about 8,000 Å. The thicknesses of the first dielectric film 330a and the second dielectric film 330b may be adjusted to provide sufficient protection, such as protection from the etch processes and/or isolation/passivation. Other materials, including other oxides, other nitrides, SiON, SiC, low k dielectric materials (e.g., Black Diamond), and/or high k oxides (e.g., HfO₂, Ta₂O₅).

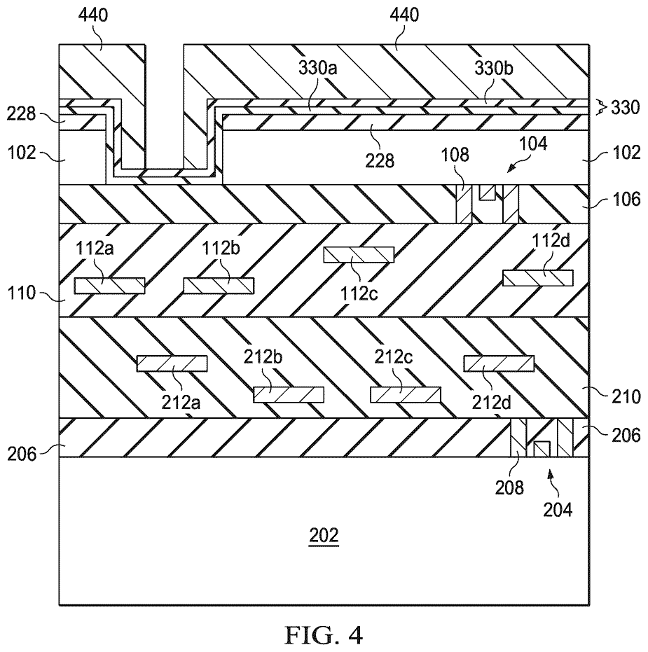

FIG. 4 illustrates a patterned mask 440 formed over the backside of the first substrate 102 in accordance with an embodiment. The patterned mask 440 may be, for example, a photoresist material that has been deposited, masked, exposed, and developed as part of a photolithography process. The patterned mask 440 is patterned to define a via opening extending through the one or more ILD layers 110 of the first substrate 102 and at least some of the one or more ILD layers 210 of the second substrate 202, thereby exposing portions of select ones of the first interconnect lines 112 and the second interconnect lines 212, as explained in greater detail below.

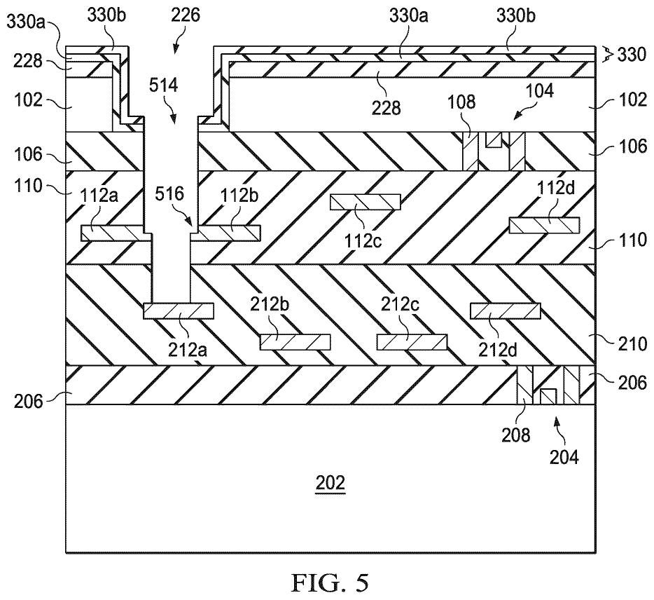

FIG. 5 illustrates the semiconductor device shown in FIG. 4 after one or more additional etching processes are performed in accordance with an embodiment. A suitable etching process, such as a dry etch, an anisotropic wet etch, or any other suitable anisotropic etch or patterning process, may be performed on the semiconductor device to form a second opening 514.

As illustrated in FIG. 5, the second opening 514 extends the first opening 226 to the first interconnect lines 112a and 112b and to the second interconnect line 212a. In an embodiment, the first interconnect lines 112a and 112b are formed of suitable metal materials such as copper, which exhibits a different etching rate (selectivity) than the first ILD layers 110. As such, the first interconnect lines 112a and 112b function as a hard mask layer for the etching process of the first ILD layers 110. A selective etching process may be employed to etch the first ILD layers 110 rapidly while etching only a portion of the first interconnect lines 112a and 112b. As shown in FIG. 5, the exposed portion of the first interconnect lines 112a and 112b may be partially etched away, thereby forming a recess 516, as the etch process continues toward the second interconnect line 212a. The depth of the recess 516 may vary depending on a variety of applications and design needs.

The second etch process continues until the second interconnect line 212a is exposed, thereby forming a combined opening extending from a backside of the first wafer 100 to the second interconnect line 212a of the second wafer 200 as illustrated in FIG. 5.

It should be noted that the second etch process may extend through a variety of various layers used to form the first ILD layers 110 and the second ILD layers 210, which may include various types of materials and etch stop layers. Accordingly, the second etch process may utilize multiple etchants to etch through the various layers, wherein the etchants are selected based upon the materials being etched.

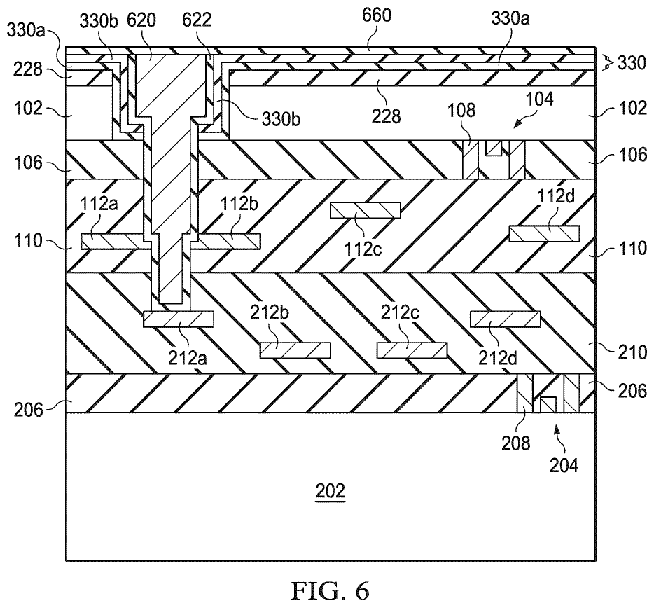

FIG. 6 illustrates a conductive material formed within the first opening 226 (see FIG. 5) and the second opening 514 (see FIG. 5) in accordance with various embodiments. In an embodiment, the conductive material may be formed by depositing one or more diffusion and/or barrier layers 622 and depositing a seed layer. For example, a diffusion barrier layer comprising one or more layers of Ta, TaN, TiN, Ti, CoW, or the like is formed along the sidewalls of the first opening 310 and the second opening 514. The seed layer (not shown) may be formed of copper, nickel, gold, any combination thereof and/or the like. The diffusion barrier layer and the seed layer may be formed by suitable deposition techniques such as PVD, CVD and/or the like. Once the seed layer has been deposited in the openings, a conductive material, such as tungsten, titanium, aluminum, copper, any combinations thereof and/or the like, is filled into the first opening 310 and the second opening 514, using, for example, an electro-chemical plating process, thereby forming a conductive plug 620.

FIG. 6 also illustrates removal of excess materials, e.g., excess conductive materials, from the backside of the first substrate 102. In embodiments, one or more of the layers of the multi-layer dielectric film 330 may be left along a backside of the first substrate 102 to provide additional protection from the environment. In the example illustrated in FIG. 6, the first dielectric film 330a and the second dielectric film 330b of the multi-layer dielectric film 330 remain. In this example, the excess materials may be removed using an etch process, a planarization process (e.g., a CMP process), or the like, using the second dielectric film 330b as a stop layer.

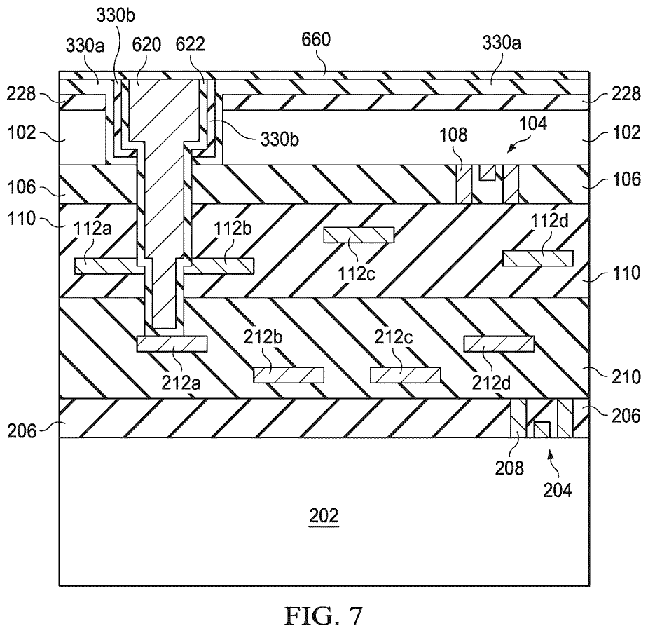

FIG. 7 illustrates another example in which the second dielectric film 330b along the backside of the first substrate 102 is removed. In this example, the first dielectric film 330a may act as a stop layer for an etch or planarization process, or the like, to remove the excess second dielectric film 330b.

FIGS. 6 and 7 further illustrate a dielectric capping layer 660 formed along a backside of the first wafer 100. The dielectric capping layer 660 may comprise one or more layers of dielectric materials, such as silicon nitride, silicon oxynitride, silicon oxycarbide, silicon carbide, combinations thereof, and multi-layers thereof. The dielectric capping layer 660 may have a thickness from about 200 Å to about 6,000 Å, and be formed by, for example, using suitable deposition techniques such as sputtering, CVD and the like.

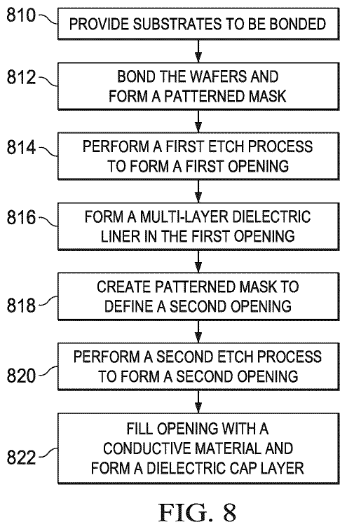

FIG. 8 is a flowchart illustrating a method of forming stacked chip configuration in accordance with an embodiment. The method begins in step 810, wherein substrates to be bonded are provided. The substrates may be processed wafers (such as those illustrated in FIG. 1), dies, a wafer and a die, or the like. In step 812, the substrates are bonded and a patterned mask is formed thereon, the patterned mask defining an opening for a contact plug to be subsequently formed, such as that discussed above with reference to FIG. 2. Optionally, an ARC layer and/or one or more hard mask layers are formed.

Thereafter, in step 814, a first etch process is performed to etch through a first substrate of the first wafer, such as discussed above with reference to FIG. 3, thereby forming a first opening. In step 816, a multi-layer dielectric film is formed within the first opening and along a backside of the first substrate, and in step 818, a patterned mask, as discussed above with reference to FIG. 4, is formed to define a second opening to contact select ones of the interconnects formed on the first substrate and/or the second substrate. In step 820, another etch process is used to create the second opening, which exposes portions of the interconnects on the first substrate and/or the second substrate, as discussed above with reference to FIG. 5. The opening is filled with a conductive material in step 822, such as that discussed above with reference to FIGS. 6 and 7. A dielectric cap layer may be formed over the conductive material, such as that discussed above with reference to FIGS. 6 and 7.

In an embodiment, an apparatus is provided. The apparatus includes a first chip and a second chip. The first chip has a first substrate, a plurality of first dielectric layers and a plurality of first metal lines formed in the first dielectric layers over the first substrate. The second chip has a surface bonded to a first surface of the first semiconductor chip, wherein the second chip has a second substrate, a plurality of second dielectric layers and a plurality of second metal lines formed in the second dielectric layers over the second substrate. A first opening having a first width is in the first substrate, and a second opening extends from a bottom of the first opening through the plurality of first dielectric layers and into the plurality of second dielectric layers, wherein the second opening has a second width less than the first width. A conductive plug is in the first opening and the second opening. A plurality of liners is interposed between the conductive plug and the first substrate such that the plurality of liners extending along a bottom of the first opening. At least one of the plurality of liners does not extend between the conductive plug and the plurality of first dielectric layers of the first chip.

In another embodiment, a method is provided. The method includes providing a first chip, wherein the first chip has a substrate and a plurality of dielectric layers, the plurality of dielectric layers having metallization layers formed therein. A first surface of the plurality of dielectric layers of the first chip is bonded to a surface of a second chip. A first opening extending into a backside of the substrate is formed, and a plurality of liners are formed along sidewalls and a bottom of the first opening. A second opening extending from a bottom of the first opening through the plurality of dielectric layers to a metallization layer in the second chip is formed, and a conductive material is formed in the first opening and the second opening.

In yet another embodiment, another method is provided. The method includes providing a bonded structure having a first substrate bonded to a second substrate, the first substrate having one or more overlying first dielectric layers and a first conductive interconnect in the one or more first dielectric layers, the second substrate having one or more overlying second dielectric layers and a second conductive interconnect in the one or more second dielectric layers, the first substrate being bonded to the second substrate such that the first dielectric layers face the second dielectric layers. A first opening is formed extending through the first substrate, and a plurality of dielectric layers are formed along sidewalls and a bottom of the first opening. After the forming the plurality of dielectric layers, a second opening is formed extending from the first opening to a first pad formed in at least one of the first dielectric layers and a second pad formed in at least one of the second dielectric layers. A conductive plug is formed in the first opening and the second opening.

In yet another embodiment, an apparatus is provided. The apparatus includes: a first semiconductor chip including a first substrate, a plurality of first dielectric layers over the first substrate, and a plurality of first metal lines in the plurality of first dielectric layers; a second semiconductor chip having a second surface bonded to a first surface of the first semiconductor chip, where the second semiconductor chip includes a second substrate, a plurality of second dielectric layers over the second substrate and a plurality of second metal lines in the plurality of second dielectric layers; a conductive plug including a first portion having a first width and a second portion having a second width, the second width being less than the first width, the first portion extending through the first substrate, the second portion extending through the plurality of first dielectric layers and into the plurality of second dielectric layers; and a plurality of liners interposed between the conductive plug and the first substrate, the plurality of liners extending along a bottom of the first portion of the conductive plug, at least one of the plurality of liners not extending between the conductive plug and the plurality of first dielectric layers, topmost surfaces of the plurality of liners being level with a topmost surface of the conductive plug.

In yet another embodiment, an apparatus is provided. The apparatus includes: a bonded structure including a first semiconductor chip and a second semiconductor chip, the first semiconductor chip including a first substrate, one or more first dielectric layers on the first substrate and a first conductive interconnect in the one or more first dielectric layers, the second semiconductor chip including a second substrate, one or more second dielectric layers on the second substrate and a second conductive interconnect in the one or more second dielectric layers, the first dielectric layers and the second dielectric layers being interposed between the first substrate and the second substrate; a conductive plug electrically connecting the first semiconductor chip to the second semiconductor chip, the conductive plug including: a first portion extending from a first surface of the first substrate toward a second surface of the first substrate, the first portion having a first width; a second portion extending from the second surface of the first substrate to the first conductive interconnect, the second portion having a second width less than the first width; and a third portion extending from the first conductive interconnect to the second conductive interconnect, the third portion having a third width less than the second width; a first liner extending along a sidewall and a bottom surface of the first portion of the conductive plug, a topmost surface of the first liner being level with a topmost surface of the conductive plug; and a second liner including a first portion and a second portion, the first portion of the second liner being interposed between the first liner and the first substrate, the second portion of the second liner extending along the first surface of the first substrate, a topmost surface of the second liner being level with the topmost surface of the first liner.

In yet another embodiment, an apparatus is provided. The apparatus includes: a first substrate having a first surface and a second surface, the first surface being opposite the second surface; a second substrate having a third surface and a fourth surface, the third surface being opposite the fourth surface, the second surface facing the third surface; a plurality of dielectric layers interposed between the second surface of the first substrate and the third surface of the second substrate; a plurality of conductive interconnects in the plurality of dielectric layers; a conductive plug extending from the first surface of the first substrate to a first conductive interconnect of the plurality of conductive interconnects through a second conductive interconnect of the plurality of conductive interconnects, the conductive plug electrically connecting the first conductive interconnect of the plurality of conductive interconnects to the second conductive interconnect of the plurality of conductive interconnects, a width of the conductive plug decreasing as the conductive plug extends through the second conductive interconnect of the plurality of conductive interconnects toward the first conductive interconnect of the plurality of conductive interconnects; a first liner between a sidewall the conductive plug and the first substrate, a topmost surface of the first liner being level with a topmost surface of the conductive plug; and a second liner between the first liner and the first substrate, a portion of the second liner extending along the first surface of the first substrate, a topmost surface of the second liner being level with the topmost surface of the conductive plug.

Although embodiments of the present invention and its advantages have been described in detail, it should be understood that various changes, substitutions and alterations can be made herein without departing from the spirit and scope of the invention as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor device comprising:
a first semiconductor chip, wherein the first semiconductor chip comprises a first substrate, a plurality of first dielectric layers below the first substrate, and a plurality of first metal lines in the plurality of first dielectric layers;
a second semiconductor chip bonded to the first semiconductor chip, wherein the second semiconductor chip comprises a second substrate, a plurality of second dielectric layers above the second substrate, and a plurality of second metal lines in the plurality of second dielectric layers;
a conductive plug, wherein the a first portion of the conductive plug extends in the first substrate, a second portion of the conductive plug extends in the plurality of first dielectric layers, and a third portion of the conductive plug extends in the plurality of second dielectric layers; and
a plurality of insulating liners between the conductive plug and the first substrate, wherein the plurality of insulating liners comprises a nitride liner and an oxide liner, wherein a sidewall of the nitride liner is in contact with the first substrate, and wherein top surfaces of the nitride liner and the oxide liner are level with a top surface of the conductive plug.

2. The semiconductor device of claim 1, wherein the first portion of the conductive plug has a first width, the second portion of the conductive plug has a second width, the third portion of the conductive plug has a third width, wherein the the second width is smaller than the first width, and wherein the third width is smaller than the second width.

3. The semiconductor device of claim 1, wherein a first portion of the nitride liner is above a top surface of the first substrate.

4. The semiconductor device of claim 3, wherein a second portion of the nitride liner is below a bottom surface of the first portion of the conductive plug.

5. The semiconductor device of claim 1, further comprising a diffusion barrier layer, wherein the diffusion barrier layer is between the conductive plug and the plurality of first dielectric layers, wherein the diffusion barrier layer is between the conductive plug and the plurality of second dielectric layers, wherein the diffusion barrier layer is in contact with a first metal line of the plurality of first metal lines, and wherein the diffusion barrier layer is in contact with a first metal line of the plurality of second metal lines.

6. The semiconductor device of claim 5, wherein the diffusion barrier layer is between the conductive plug and the plurality of insulating liners, and wherein the diffusion barrier layer is in contact with the nitride liner and the oxide liner.

7. The semiconductor device of claim 1, further comprising an inter-layer dielectric layer between the first substrate and the plurality of the first dielectric layers, wherein a bottom surface of the nitride liner is in contact with a top surface of the inter-layer dielectric layer.

8. A semiconductor device comprising:
a bonded structure comprising a first semiconductor chip and a second semiconductor chip, wherein the first semiconductor chip comprises a first substrate, one or more first dielectric layers on the first substrate, a first conductive feature in the one or more first dielectric layers, and an inter-layer dielectric layer between the first substrate and the one or more first dielectric layers, wherein the second semiconductor chip comprises a second substrate, one or more second dielectric layers on the second substrate, and a second conductive feature in the one or more second dielectric layers, and wherein the one or more first dielectric layers and the one or more second dielectric layers are between the first substrate and the second substrate;
a conductive plug electrically connecting the first semiconductor chip to the second semiconductor chip, wherein the conductive plug comprises a first portion extending from a plane of a first surface of the first substrate toward a second surface of the first substrate;
an oxide liner extending along a sidewall and a bottom surface of the first portion of the conductive plug;
a nitride liner extending along the sidewall and the bottom surface of the first portion of the conductive plug, wherein the oxide liner is between the first portion of the conductive plug and the nitride liner, wherein a bottom surface of the nitride liner is in contact with a top surface of the inter-layer dielectric layer; and
a capping layer over the conductive plug, the oxide liner, and the nitride liner.

9. The semiconductor device of claim 8, wherein the nitride liner comprises a first portion between the oxide liner and the first substrate and a second portion over the first surface of the first substrate, wherein the first portion of the nitride liner is in contact with the first substrate, and wherein the second portion of the nitride liner is separated from the first substrate.

10. The semiconductor device of claim 9, further comprising an anti-reflection coating (ARC) layer between the first substrate and the second portion of the nitride liner, wherein the nitride liner is in contact with a sidewall of the ARC layer.

11. The semiconductor device of claim 8, wherein a top surface of the oxide liner is level with a top surface of the conductive plug, and wherein a top surface of the nitride liner is level with the top surface of the conductive plug.

12. The semiconductor device of claim 8, wherein the oxide liner is a single material layer, and wherein the nitride liner is a single material layer.

13. The semiconductor device of claim 8, wherein the conductive plug further comprises:
a second portion extending from a plane of the second surface of the first substrate to a plane of a first surface of the first conductive feature, wherein the second portion of the conductive plug is narrower than the first portion of the conductive plug; and
a third portion extending from the plane of the first surface of the first conductive feature toward the second conductive feature, wherein the third portion of the conductive plug is narrower than the second portion of the conductive plug.

14. The semiconductor device of claim 8, wherein the first semiconductor chip is a backside illumination sensor, and wherein the second semiconductor chip is a logic device.

15. A semiconductor device comprising:
a first substrate having a first surface and a second surface, wherein the first surface is opposite the second surface;
a second substrate having a third surface and a fourth surface, wherein the third surface is opposite the fourth surface, and wherein the second surface faces the third surface;
a plurality of dielectric layers between the second surface and the third surface;
a plurality of conductive features in the plurality of dielectric layers;
a conductive plug extending from a plane level with the first surface toward a first conductive feature of the plurality of conductive features through a second conductive feature of the plurality of conductive features, wherein the conductive plug electrically connects the first conductive feature to the second conductive feature;
an oxide liner, wherein a first portion of the oxide liner is between the conductive plug and the first substrate, and wherein a second portion of the oxide liner is between the conductive plug and the plurality of dielectric layers;
a nitride liner, wherein a first portion of the nitride liner is between the first portion of the oxide liner and the first substrate, wherein a second portion of the nitride liner is between the second portion of the oxide liner and the plurality of dielectric layers, wherein a third portion of the nitride liner is over the first surface, and wherein the conductive plug extends across an interface between the oxide liner and the nitride liner;
a barrier layer between the conductive plug and the oxide liner, wherein the barrier layer is in contact with the first conductive feature and the second conductive feature; and
an anti-reflection coating (ARC) layer between the first surface and the nitride liner, wherein the ARC layer is in contact with the nitride liner.

16. The semiconductor device of claim 15, wherein a top surface of the oxide liner, a top surface of the nitride liner, and a top surface of the conductive plug are level.

17. The semiconductor device of claim 16, further comprising a capping layer in contact with the top surface of the oxide liner, the top surface of the nitride liner, and the top surface of the conductive plug.

18. The semiconductor device of claim 15, wherein the first portion of the nitride liner is in contact with the first substrate.

19. The semiconductor device of claim 15, further comprising an inter-layer dielectric layer between the second surface and the plurality of dielectric layers, wherein the second portion of the nitride liner is in contact with the inter-layer dielectric layer.

20. The semiconductor device of claim 15, wherein a width of the conductive plug decreases as the conductive plug extends from the plane level with the first surface toward the first conductive feature.
